(19) United States
(12) Patent Application Publication
(10) Pub. No.: US 2025/0338684 A1
(43) Pub. Date: Oct. 30, 2025

(54) METHOD FOR REMOVING ELECTRONIC COMPONENT FROM SUBSTRATE AND METHOD FOR MANUFACTURING LIGHT EMITTING DIODE DISPLAY

(71) Applicant: Micraft System Plus Co., Ltd., Taoyuan City (TW)

(72) Inventors: Sheng-Che Huang, Taoyuan City (TW); Ching-Ju Lin, Taoyuan City (TW); Yu-Hui Liu, Taoyuan City (TW)

(73) Assignee: Micraft System Plus Co., Ltd., Taoyuan City (TW)

(21) Appl. No.: 19/071,724

(22) Filed: Mar. 5, 2025

Related U.S. Application Data
(60) Provisional application No. 63/638,438, filed on Apr. 25, 2024.

(30) Foreign Application Priority Data
Jul. 15, 2024 (TW) 113126439

(51) Int. Cl. H10H 29/02

(52) U.S. Cl. CPC H10H 29/02

(57) ABSTRACT

Disclosed herein is a method for removing an electronic component from a substrate. The electronic component is fixed on the substrate via an adhesive force generated by a solder. The method includes applying an energy to the electronic component to reduce the adhesive force, and applying an adhesion removal force to the electronic component. The adhesion removal force is sufficient to overcome the adhesive force of the solder after the adhesive force is reduce by the energy, so as to remove the electronic component from the substrate. Also, disclosed herein is a method for manufacturing light emitting diode display, including using the method as mentioned previously to repair a light emitting diode on the substrate.

### CROSS REFERENCE TO RELATED APPLICATIONS

This application claims the benefit of U.S. Provisional Application No. 63/638,438, filed on Apr. 25, 2024. The content of the application is incorporated herein by reference.

### BACKGROUND OF THE INVENTION

### 1. Field of the Invention

The present disclosure relates to a method for removing an electronic component, and more specifically, to a method for applying an energy to desolder a damaged or defective LED chip and applying an adhesion removal force to remove the LED chip from a substrate.

### 2. Description of the Prior Art

Currently, light emitting diodes (LEDs) are widely used due to the excellent lighting quality and high luminous efficiency. In general, for improving the color expression ability of an LED display, the prior art utilizes combination of red, green and blue LED chips to make the LED display have a full-color display function. This full-color LED display can mix red, green and blue light respectively emitted by the red, green and blue LED chips to form a full-color light for subsequent image display. However, in the prior art, when the LED chip fixed on the circuit substrate is damaged, the damaged LED chip cannot be removed and repaired, thereby greatly affecting the production yield and capacity of the LED display.

### SUMMARY OF THE INVENTION

Accordingly, the present disclosure aims to provide a method for removing a LED chip from a substrate via providing energy to the damaged or defective LED chip for desoldering and applying an adhesion removal force to remove the LED chip, thereby solving the above-mentioned issue.

According to an embodiment, the present disclosure provides a method for removing an electronic component from a substrate. The electronic component is fixed on the substrate via an adhesive force generated by a solder. The method includes applying an energy to the electronic component to reduce the adhesive force and applying an adhesion removal force to the electronic component. The adhesion removal force is sufficient to overcome the adhesive force of the solder after the adhesive force is reduced by the energy thereby removing the electronic component from the substrate.

According to another embodiment, the present disclosure further provides a method for manufacturing an LED display using the aforesaid method to repair an LED chip on the substrate.

These and other objectives of the present disclosure will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross-sectional diagram of a pressing component being aligned with an electronic component according to an embodiment of the present disclosure.

FIG. 2 is a cross-sectional diagram of the pressing component in FIG. 1 pressing a flexible body to contact the electronic component.

FIG. 3 is a cross-sectional diagram of the pressing component in FIG. 2 releasing the flexible body for removing the electronic component from a substrate via the flexible body.

FIG. 4 is a cross-sectional diagram of a pressing component with an adhesive material being aligned with the electronic component according to another embodiment of the present disclosure.

### DETAILED DESCRIPTION

The present disclosure will now be described more specifically with reference to the following embodiments and the accompanying drawings. Other advantages and effects of the present disclosure can be easily understood by a person ordinarily skilled in the art in view of the detailed descriptions and the accompanying drawings. The present disclosure can be implemented or applied to other different embodiments. Certain aspects of the present disclosure are not limited by the particular details of the examples illustrated herein. Without departing from the spirit and scope of the present disclosure, the present disclosure will have other modifications and changes. It should be understood that the appended drawings are not necessarily drawn to the scale and configuration of each component (e.g., number and arrangement of electronic components, and sizes and structural designs of a pressing component and the electronic components) in the drawings is merely illustrative, not presenting an actual condition of the embodiments.

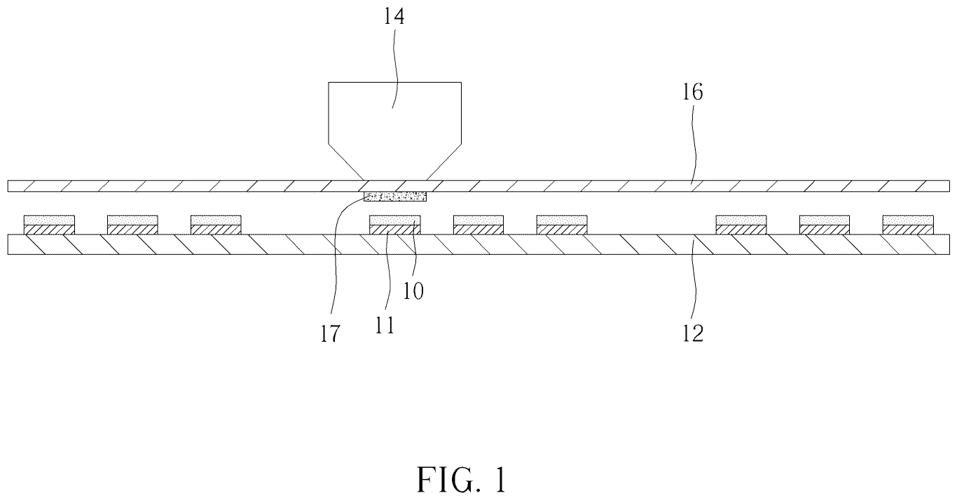

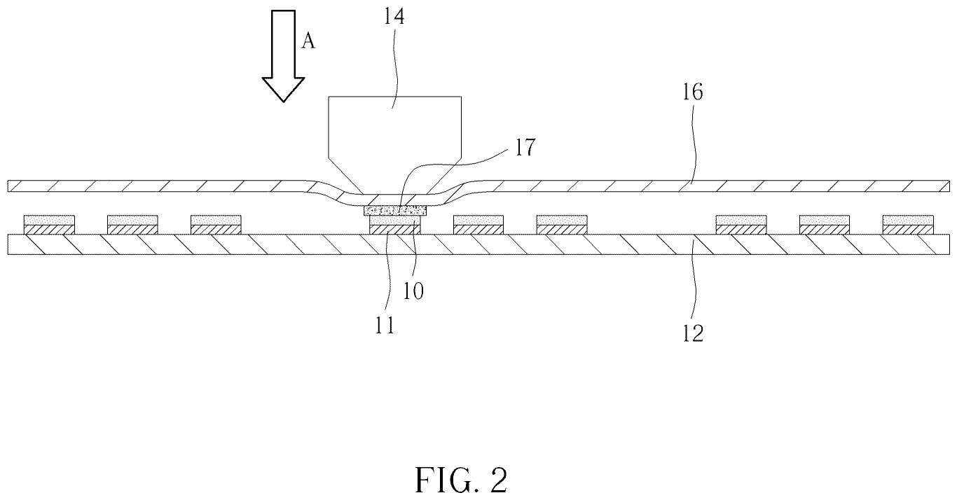

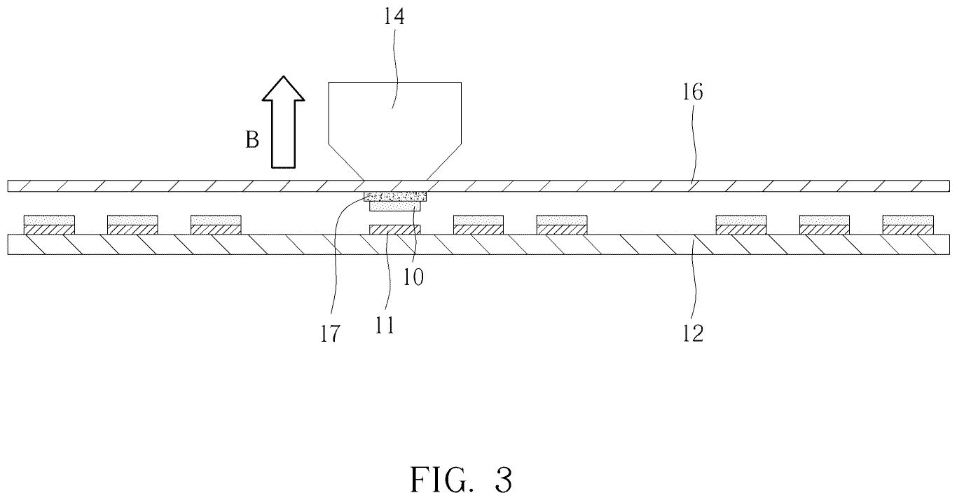

Please refer to FIGS. 1-3, which are cross-sectional diagrams showing a method for removing an electronic component 10 from a substrate 12 according to an embodiment of the present disclosure. FIG. 1 is a cross-sectional diagram of a pressing component 14 being aligned with the electronic component 10 according to an embodiment of the present disclosure. FIG. 2 is a cross-sectional diagram of the pressing component 14 in FIG. 1 pressing a flexible body 16 to contact the electronic component 10. FIG. 3 is a cross-sectional diagram of the pressing component 14 in FIG. 2 releasing the flexible body 16 for removing the electronic component 10 from the substrate 12 via the flexible body 16. The electronic component 10 could be an LED chip (e.g., a red, green or blue LED chip, but not limited thereto, meaning that the electronic component 10 could be other electronic component mounted on the substrate 12) and is fixed on the substrate 12 via an adhesive force generated by a solder 11. The substrate 12 could be preferably a thin film transistor (TFT) substrate for mounting electronic components thereon (but not limited thereto, meaning that the substrate 12 could also be other substrate suitable for mounting electronic components thereon, such as a silicon substrate or a circuit board). The flexible body 16 could be any thin film with flexibility known in the art (e.g., a silicone film, but not limited thereto). The flexible body 16 is resistant to the laser beam, so that the flexible body 16 can be penetrated by the laser beam without being burned. The pressing component 14 could be, for example, a pin, and could be driven to press the substrate 12 by an actuating mechanism (e.g., a servo motor, a voice coil motor, or a stepping motor). As for the related description for the actuating design of the actuating mechanism to drive the pressing component 14 to perform alignment, downward pressing, upward movement and other displacement actions, it is commonly known in the prior art and omitted herein.

As shown in FIG. 1, when the electronic component 10 fixed on the substrate 12 via a solder 11 is damaged or defective, the first step is to align the pressing component 14 with the damaged or defective electronic component 10. For example, an image sensor (e.g., a charge coupled device (CCD)) could be utilized to capture a position of the electronic component 10 on the substrate 12 to generate position information (e.g., coordinates of the electronic component 12). Next, a control unit (e.g., an industrial computer or a programmable logic controller (PLC)) could automatically control the pressing component 14 to move to a position aligned with the electronic component 10 according to the position information transmitted by the image sensor; or, an operator could manually align the pressing component 14 with the electronic component 10 according to the position information transmitted by the image sensor.

Subsequently, as shown in FIG. 2, after the aforementioned alignment step is completed, the pressing component 14 could be driven by the actuating mechanism to move toward the substrate 12 along a downward pressing direction A, so that the pressing component 14 can presses the flexible body 16 to cause deformation of the flexible body 16 until the flexible body 16 contacts the electronic component 10 fixed on the substrate 12. At this time, the pressing component 14 stops pressing the electronic component 10 and no longer moves toward the substrate 12, but the flexible body 16 still maintains contact with the electronic component 10.

During the aforesaid process, an energy could be applied to the electronic component 10 to reduce an adhesive force generated by the solder 11. According to one embodiment of the present disclosure, the energy is a thermal energy generated by a laser beam emitted by a laser generation module (e.g., an infrared laser beam, a visible laser beam, or an ultraviolet laser beam, but not limited thereto, meaning that the energy could also be an energy generated by other types of beams, such as an infrared beam). Specifically, the laser beam is applied to the electronic component 10 via passing through the pressing component 14 and the flexible body 16 sequentially to provide the thermal energy to the solder 11, thereby reducing the adhesive force generated by the solder 11 for weakening a bonding force between the electronic component 10 and the substrate 12. Accordingly, the pressing component 14 could be made of material that allows the laser beam to penetrate (e.g., quartz, sapphire or diamond material); or, the pressing component 14 is provided with a channel for the laser beam to pass through. In another embodiment, the laser beam generated by the laser generation module could apply the thermal energy to the electronic component 10 without passing through the pressing component 14. For example, the laser generation module could be disposed at a position offset from an extension line of a longitudinal direction of the pressing component 14, and is oblique relative to the electronic component 10 (an angle between the laser beam and the substrate 12 is less than 90 degrees). That is, the laser generation module could be tilted to obliquely emit the laser beam, or a light guide could be utilized to change a traveling path of the laser beam and guide the laser beam to the electronic component 10.

To be noted, the step of applying the energy to the electronic component 10 for reducing the adhesive force generated by the solder 11 is not limited to the aforesaid embodiment of projecting the laser beam toward the substrate 12 through the pressing component 14. For example, in another embodiment, the laser generation module could also be disposed under the substrate 12, so that the laser beam can be projected from a bottom of the substrate 12 to a soldering position of the electronic component 10 for desoldering.

In another embodiment, a heating module could be disposed under the substrate 12 to provide the thermal energy penetrating the substrate 12 to heat the solder 11 for desoldering; or, a heating module could be disposed on the pressing component 14 to transmit the thermal energy from the electronic component 10 to the solder 11 for desoldering.

Furthermore, the energy utilized by the present disclosure for reducing the adhesive force of the solder could also be a mechanical energy to physically destroy adhesion between the electronic component and the solder (e.g., applying a scraping force to the electronic component for generating a kinetic energy to loosen the adhesion between the electronic component and the solder, but not limited thereto).

As shown in FIG. 3, after the aforesaid step of applying the energy to the electronic component 10 for reducing the adhesive force generated by the solder 11, an adhesion removal force could be applied to the electronic component 10 for overcoming the adhesive force of the solder 11 after the adhesive force is reduced by the energy and removing the electronic component 10 from the substrate 12 for subsequent repair operations (e.g., utilizing a placing module, such as a vacuum nozzle, to place an undamaged electronic component at the original mounting position of the electronic component 10). To be more specific, the adhesion removal force could be generated by the pressing component 14 pressing the flexible body 16 having an unpressed side coated with an adhesive material 17. In such a manner, after the pressing component 14 is driven by the actuating mechanism to press the flexible body 16 along the downward pressing direction A to cause deformation of the flexible body 16, and further to cause the adhesive material 17 to contact the electronic component 10 (as shown in FIG. 2), the pressing component 14 could then be driven by the actuating mechanism to move away from the substrate 12 along an upward moving direction B, thereby no longer applying a pressing force to the flexible body 16. When the flexible body 16 returns to its original state due to its material characteristic (i.e., elasticity), the adhesive material 17 generates the adhesion removal force onto the electronic component 10 that is sufficient to overcome the adhesive force of the solder 11 after the adhesive force is reduced by the energy, so as to remove the electronic component 10 from the substrate 12 (as shown in FIG. 3). In another embodiment of the present disclosure, the adhesion removal force could be generated by the flexible body having adhesiveness and elasticity after receiving the thermal energy.

In practical application, it is preferred to simultaneously perform the step of applying the energy to the electronic component 10 for reducing the adhesive force generated by the solder 11, and the step of utilizing the pressing component 14 to press the flexible body 16 until the adhesive material 17 contacts the electronic component 10 via deformation of the flexible body 16 (as shown in FIG. 2), but the present disclosure is not limited thereto. For example, in another embodiment, the step of applying energy to desolder the electronic component 10 could also be performed before deformation of the flexible body 16 caused by the pressing component 14 makes the adhesive material 17 contact the electronic component 10. That is, before the adhesive material 17 contacts the electronic component 10, the laser beam generated by the laser generation module could be first projected onto the electronic component 10, or the heating module could be utilized to provide the thermal energy, for reducing the adhesive force generated by the solder 11, thereby achieving the desoldering purpose. The aforesaid method is only used to illustrate one embodiment of the present disclosure, and is not used to limit the present disclosure. A person skilled in the art can adjust the time point of providing the energy for desoldering according to actual operational requirements.

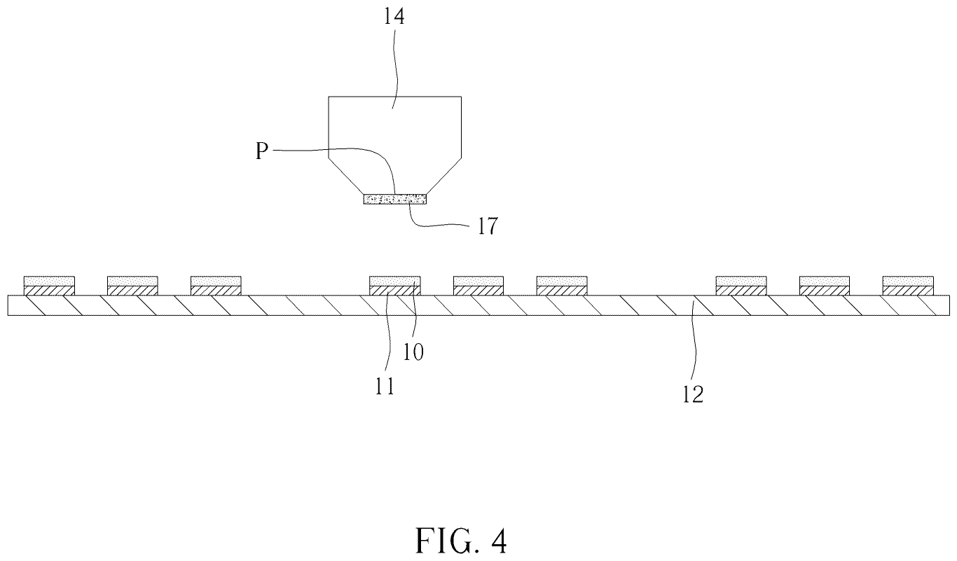

In addition, the method of providing the adhesion removal force of the present disclosure is not limited to the aforementioned embodiments. In another embodiment, the adhesion removal force could be directly provided by the pressing component. For example, please refer to FIG. 4, which is a cross-sectional diagram of the pressing component 14 with the adhesive material 17 being aligned with the electronic component 10 according to another embodiment of the present disclosure. Components both mentioned in this embodiment and the aforesaid embodiments represent components with similar structures or functions, and the related description is omitted herein. As shown in FIG. 4, the adhesion removal force for removing the electronic component 10 from the substrate 12 could be directly generated by the pressing component 14. That is, in this embodiment, the flexible body 16 could be omitted, and the adhesive material 17 could be directly coated on a pressing end portion P of the pressing component 14. As such, when an electronic component fixed on the substrate 12 is damaged or defective (e.g., the electronic component 10 shown in FIG. 4), an image recognition method could be adopted to align the pressing component 14 with the damaged or defective electronic component 10. Subsequently, the pressing component 14 could be driven by the actuating mechanism to perform a pressing action toward the substrate 12 until the adhesive material 17 of the pressing component 14 contacts the electronic component 10. During the aforesaid process, the energy could be applied to the electronic component 10 to reduce the adhesive force generated by the solder 11. Finally, the pressing component 14 could be driven by the actuating mechanism to move away from the substrate 12 in an opposite direction. At the same time, the adhesion removal force is applied to the electronic component 10 via the adhesiveness of the adhesive material 17 that is sufficient to overcome the adhesive force reduced by the energy, thereby removing the electronic component 10 from the substrate 12 for subsequent repair operations. As for other designs of this embodiment (e.g., the energy application method and the energy application timing), the related description could be reasoned by analogy according to the aforesaid embodiments and omitted herein.

Another embodiment of the present disclosure is a method for manufacturing a light emitting diode display, which utilizes the aforementioned method of removing the electronic component from the substrate to repair a defective electronic component (i.e., an LED, such as a mini-LED and/or a micro-LED) on a circuit substrate, and the substrate 12 could be used as a display substrate for an end product. After repairing all damaged or defective LED chips by using the aforesaid method, it can be ensured that the LED chips mounted on the substrate 12 can function properly to form a light emitting diode display with an image display function. Specifically, the present disclosure can apply the energy to desolder the damaged or defective LED chip and apply the adhesion removal force to remove the LED chip from the substrate, so that the damaged or defective LED chip can be smoothly removed and replaced by an undamaged LED chip to achieve the repair effect. Thus, the present disclosure can effectively solve the prior art problem that the damaged LED chip cannot be removed and repaired, so as to greatly improve the production yield and capacity of the LED display.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for removing an electronic component from a substrate, wherein the electronic component is fixed on the substrate via an adhesive force generated by a solder, the method comprising:
applying an energy to the electronic component to reduce the adhesive force; and
applying an adhesion removal force to the electronic component, the adhesion removal force being sufficient to overcome the adhesive force of the solder after the adhesive force is reduced by the energy thereby removing the electronic component from the substrate.

2. The method of claim 1, wherein the energy is a thermal energy.

3. The method of claim 2, wherein the thermal energy is generated by a laser beam.

4. The method of claim 1, wherein the adhesion removal force is generated by a pressing component pressing a flexible body having an unpressed side coated with an adhesive material to cause deformation of the flexible body and further to cause the adhesive material on the flexible body to contact the electronic component, and then releasing the flexible body to its original shape.

5. The method of claim 4, wherein the energy is applied to the electronic component via passing through the pressing component.

6. The method of claim 4, wherein the energy is applied to the electronic component when the pressing component presses the flexible body to cause the deformation of the flexible body and before the adhesive material contacts the electronic component.

7. The method of claim 4, wherein the energy is applied to the electronic component when the pressing component presses the flexible body to cause the deformation of the flexible body and further to cause the adhesive material to contact the electronic component.

8. The method of claim 1, wherein the adhesion removal force is generated by a pressing component, the pressing component has a pressing end portion coated with an adhesive material, and the adhesion removal force is generated by the pressing component pressing the electronic component in a direction and then moving in an opposite direction.

9. The method of claim 8, wherein the energy is applied to the electronic component via passing through the pressing component.

10. The method of claim 1, wherein the electronic component is an LED (Light Emitting Diode) chip.

11. A method for manufacturing an LED display using the method of claim 10 to repair an LED chip on the substrate.
